(19) United States
(12) Patent Application Publication
(10) Pub. No.: US 2026/0182065 A1
(43) Pub. Date: Jun. 25, 2026

(54) IMAGE SENSOR AND ELECTRONIC APPARATUS COMPRISING IMAGE SENSOR

(71) Applicant: SAMSUNG ELECTRONICS CO., LTD., Suwon-si (KR)

(72) Inventor: HEESANG KWON, Suwon-si (KR)

(73) Assignee: SAMSUNG ELECTRONICS CO., LTD., Suwon-si (KR)

(21) Appl. No.: 19/402,240

(22) Filed: Nov. 26, 2025

(30) Foreign Application Priority Data
Dec. 19, 2024 (KR) 10-2024-0191829

(51) Int. Cl. H10F 39/00

(52) U.S. Cl. CPC H10F 39/807; H10F 39/802; H10F 39/8037; H10F 39/8063; H10F 39/811

(57) ABSTRACT

An image sensor includes a substrate including a first surface and a second surface facing the first surface in a first direction, a first pixel region and a second pixel region that are isolated by a photodiode isolation pattern in the substrate, a plurality of active regions adjacent to the first surface of the substrate, a plurality of gate electrodes on the first surface of the substrate and respectively on the plurality of active regions, a plurality of gate insulating layers respectively between the plurality of active regions and the plurality of gate electrodes, a first floating diffusion region in the first pixel region, a second floating diffusion region in the second pixel region, a connection portion on the first surface of the substrate, and an insulating pattern between the substrate and the connection portion.

### CROSS-REFERENCE TO RELATED APPLICATION

This application is based on and claims priority to Korean Patent Application No. 10-2024-0191829 filed on Dec. 19, 2024, in the Korean Intellectual Property Office, the disclosure of which is incorporated by reference herein in its entirety.

### BACKGROUND

The present disclosure relates to an image sensor and an electronic apparatus including the image sensor.

Image sensors are semiconductor devices for converting optical images into electrical signals. Image sensors may be classified into charge coupled devices (CCDs) and complementary metal oxide semiconductors (CMOSs).

As compared to CCD image sensors with high-voltage analog circuits, CMOS images sensors (CISs) have the advantages of low manufacturing costs and low power consumption due to the small sizes of the elements. Thus, CISs may be mounted in home appliances including portable devices such as smart phones, digital cameras, etc.

A pixel array constituting a CMOS image sensor may include a photodiode in each pixel. The photodiode may generate electrical signals that vary depending on the amounts of incident light, and the CMOS image sensor may synthesize an image by processing the electrical signals.

The CMOS image sensor may include a plurality of transistors for driving the photodiode.

Recently, in response to the demand for high-definition images, the pixels of image sensors are becoming smaller and the numbers of pixels are increasing. Accordingly, fast operation characteristics of transistors in an image sensor are required.

Information disclosed in this Background section has already been known to or derived by the inventors before or during the process of achieving the embodiments of the present application, or is technical information acquired in the process of achieving the embodiments. Therefore, it may contain information that does not form the prior art that is already known to the public.

### SUMMARY

One or more example embodiments provide an image sensor which may be capable of a fast operation characteristic while preventing parasitic capacitance and shorts in the image sensor, and an electronic apparatus comprising the image sensor.

Additional aspects will be set forth in part in the description which follows and, in part, will be apparent from the description, or may be learned by practice of the presented embodiments.

According to an aspect of an example embodiment, an image sensor may include a substrate including a first surface and a second surface facing the first surface in a first direction, a first pixel region and a second pixel region that are isolated by a photodiode isolation pattern in the substrate, a plurality of active regions adjacent to the first surface of the substrate, a plurality of gate electrodes on the first surface of the substrate and respectively on the plurality of active regions, a plurality of gate insulating layers respectively between the plurality of active regions and the plurality of gate electrodes, a first floating diffusion region in the first pixel region, a second floating diffusion region in the second pixel region, a connection portion on the first surface of the substrate, and an insulating pattern between the substrate and the connection portion, where the first floating diffusion region is connected to the second floating diffusion region by the connection portion and, in the first direction, a thickness of the insulating pattern is larger than a thickness of the plurality of gate insulating layers.

According to an aspect of an example embodiment, an electronic apparatus may include a lens assembly configured to form an optical image of a subject, an image sensor configured to convert the optical image formed by the lens assembly into an electrical signal, and a processor configured to process the electrical signal generated by the image sensor, where the image sensor may include a substrate including a first surface and a second surface facing the first surface in a first direction, a first pixel region and a second pixel region that are isolated by a photodiode isolation pattern in the substrate, a plurality of active regions adjacent to the first surface of the substrate, a plurality of gate electrodes on the first surface of the substrate and respectively on the plurality of active regions, a plurality of gate insulating layers respectively between the plurality of active regions and the plurality of gate electrodes, a first floating diffusion region in the first pixel region, a second floating diffusion region in the second pixel region, a connection portion on the first surface of the substrate, and an insulating pattern between the substrate and the connection portion, where the first floating diffusion region is connected to the second floating diffusion region by the connection portion and, in the first direction, a thickness of the insulating pattern is larger than a thickness of the plurality of gate insulating layers.

According to an aspect of an example embodiment, an image sensor may include a substrate including a first surface and a second surface facing the first surface in a first direction, a first pixel region and a second pixel region that are isolated by a photodiode isolation pattern in the substrate, a plurality of active regions adjacent to the first surface of the substrate, a plurality of gate electrodes on the first surface of the substrate and respectively on the plurality of active regions, a plurality of gate insulating layers respectively between the plurality of active regions and the plurality of gate electrodes, a first floating diffusion region in the first pixel region, a second floating diffusion region in the second pixel region, a connection portion on the first surface of the substrate, and an insulating pattern between the substrate and the connection portion, where, in the first direction, a thickness of the insulating pattern is larger than a thickness of the plurality of gate insulating layers, and the connection portion includes a first portion that overlaps the photodiode isolation pattern and a second portion that abuts the first floating diffusion region and the second floating diffusion region.

According to an aspect of an example embodiment, a method of manufacturing an image sensor may include stacking a first insulating layer on a substrate, forming a first etching mask pattern, performing etching on the first insulating layer, forming a second insulating layer on the insulating pattern, forming a second etching mask pattern, performing etching on the second insulating layer to form a first gate insulating layer and a second gate insulating layer, forming an upper layer on the second gate insulating layer, forming a connection portion on the insulating pattern, forming a source follower gate electrode on the first gate insulating layer, and forming a gate electrode on the second gate insulating layer.

### BRIEF DESCRIPTION OF DRAWINGS

The above and other aspects, features, and advantages of certain example embodiments of the present disclosure will be more apparent from the following description taken in conjunction with the accompanying drawings, in which:

FIG. 1 is a block diagram illustrating an image sensor according to one or more embodiments;

FIG. 2 is a plan view illustrating a portion of an image sensor according to one or more embodiments;

FIG. 3 is a diagram of an image sensor according to one or more embodiments;

FIG. 4 is a plan view of an image sensor according to one or more embodiments;

FIG. 5 is a cross-sectional view taken along line I-I′ of FIG. 4 according to one or more embodiments;

FIG. 6 is a cross-sectional view taken along line II-II′ of FIG. 4 according to one or more embodiments;

FIG. 7 is a cross-sectional view taken along line III-III′ of FIG. 4 according to one or more embodiments;

FIG. 8 is a cross-sectional view illustrating an image sensor according to one or more embodiments;

FIG. 9 is a cross-sectional view illustrating an image sensor according to one or more embodiments;

FIG. 10 is a plan view of an image sensor according to one or more embodiments;

FIG. 11 is a plan view of an image sensor according to one or more embodiments;

FIGS. 12 to 19 are cross-sectional views illustrating a method of manufacturing an image sensor according to one or more embodiments;

FIG. 20 is a block diagram illustrating an example of an electronic apparatus including an image sensor; and

FIG. 21 is a block diagram of an example of a camera according to one or more embodiments.

### DETAILED DESCRIPTION

Hereinafter, example embodiments of the disclosure will be described in detail with reference to the accompanying drawings. The same reference numerals are used for the same components in the drawings, and redundant descriptions thereof will be omitted. The embodiments described herein are example embodiments, and thus, the disclosure is not limited thereto and may be realized in various other forms.

As used herein, expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

In addition, the size and thickness of each configuration shown in the drawings are arbitrarily shown for understanding and ease of description, but this disclosure is not limited thereto. In the drawings, the thickness of layers, films, panels, regions, etc., are exaggerated for clarity. Further, in the drawings, for understanding and ease of description, the thickness of some layers and areas is exaggerated.

It will be understood that when an element or layer is referred to as being “over,” “above,” “on,” “below,” “under,” “beneath,” “connected to” or “coupled to” another element or layer, it may be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

In addition, in the entire specification, unless explicitly described to the contrary, the word “comprise”, and variations such as “comprises” or “comprising”, will be understood to imply the inclusion of stated elements but not the exclusion of any other elements.

Further, throughout the specification, when it is referred to as “connected”, this may indicate that two or more constituent elements are directly connected, but may indicate that two or more constituent elements are indirectly connected through another constituent element, are physically connected, electrically connected, or are integrated even though two or more constituent elements are referred as different names depending on a location and a function.

Terms such as first, second, etc. may be used to describe various components, but are used only for the purpose of distinguishing one component from another component. These terms do not limit the difference in the material or structure of the components.

Operations of a method may be performed in an appropriate order unless explicitly described in terms of order. In addition, the use of all illustrative terms (e.g., etc.) is merely for describing technical ideas in detail, and the scope is not limited by these examples or illustrative terms unless limited by the claims.

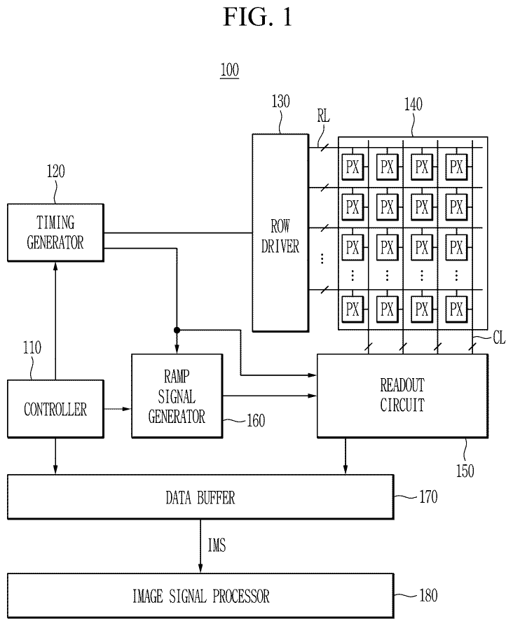

An image sensor according to one or more embodiments will be described in brief with reference to FIG. 1. FIG. 1 is a block diagram illustrating an image sensor according to one or more embodiments.

Referring to FIG. 1, an image sensor 100 according to one or more embodiments may include a pixel array 140 and a logic circuit which controls the pixel array 140.

The logic circuit may be a circuit for controlling the pixel array 140, and may include, for example, a controller 110, a timing generator 120, a row driver 130, a readout circuit 150, a ramp signal generator 160, a data buffer 170, etc.

The image sensor 100 may further include an image signal processor 180, and according to one or more embodiments, the image signal processor 180 may be positioned outside the image sensor 100. The image sensor 100 may generate an image signal by converting light received from the outside into an electrical signal. The image signal may be provided to the image signal processor 180.

The image sensor 100 may be mounted in an electronic apparatus having an image or light sensing function. For example, the image sensor 100 may be mounted in electronic apparatuses such as cameras, smart phones, wearable devices, Internet of Things (IOT) devices, home appliances, tablet personal computers (PCs), navigation devices, drones, advanced drivers assistance systems (ADASs), etc. Also, the image sensor 100 may be mounted in electronic apparatuses which are incorporated as components in vehicles, furniture, manufacturing equipment, doors, various measuring devices, etc.

The pixel array 140 may include a plurality of pixels PX, and a plurality of row lines RL and a plurality of column lines CL connected to the plurality of pixels PX.

In one or more embodiments, each pixel PX may include at least one photodiode region. The photodiode regions may detect incident light, and convert the incident light into electrical signals according to the amounts of light, i.e., into a plurality of analog pixel signals.

Each photodiode region may be a photodiode, a pinned diode, etc. Each photodiode region may be a single-photon avalanche diode (SPAD) which is applied to a three-dimensional (3D) sensor pixel.

The level of an analog pixel signal which is output from the photodiode region may be proportional to the amount of charge which is output from the photodiode region. In other words, the level of the analog pixel signal which is output from the photodiode region may be determined depending on the amount of light which enters the pixel array 140.

The plurality of row lines RL may be connected to the plurality of pixels PX. For example, a control signal that is output from the row driver 130 to a row line RL may be transferred to the gates of the transistors of a plurality of pixels PX connected to the corresponding row line RL. Each column line CL may be disposed so as to intersect the row lines RL and may be connected to a plurality of pixels PX. A plurality of pixel signals output from the plurality of pixels PX may be transferred to the readout circuit 150 through the plurality of column lines CL.

The controller 110 may control the operation timings of the above-mentioned individual constituent elements 120, 130, 150, 160, and 170, using control signals.

In one or more embodiments, the controller 110 may receive a mode signal indicating an imaging mode from an application processor, and generally control the image sensor 100 on the basis of the received mode signal. For example, the application processor may determine the imaging mode of the image sensor 100 according to various scenarios such as the intensity of illumination in the imaging environment, the user's resolution setting, a sensed or learned state, etc., and provide the determined result to the controller 110 as the mode signal.

The controller 110 may control the plurality of pixels PX of the pixel array 140, such that the pixels output pixel signals depending on the imaging mode, and the pixel array 140 may output the pixel signals of the plurality of pixels PX or the pixel signals of some of the plurality of pixels PX, and the readout circuit 150 may sample and process the pixel signals received from the pixel array 140.

The timing generator 120 may generate a signal to be a reference for the operation timings of the components of the image sensor 100. The timing generator 120 may control the timings of the row driver 130, the readout circuit 150, and the ramp signal generator 160. The timing generator 120 may provide control signals to control the timings of the row driver 130, the readout circuit 150, and the ramp signal generator 160.

The row driver 130 may generate a control signal for driving the pixel array 140, in response to the control signals of the timing generator 120, and provide the control signal to the plurality of pixels PX of the pixel array 140 through the plurality of row lines RL.

In one or more embodiments, the row driver 130 may control the pixels PX in units of a row line, such that the pixels detect incident light. Each row line unit may include at least one row line RL. For example, the row driver 130 may generate a transmission signal for controlling transfer transistors, a reset control signal for controlling reset transistors, a selection control signal for controlling selected transistors, etc., and provide the signals to the pixel array 140.

The readout circuit 150 may convert the pixel signals (or electrical signals) received from pixels PX coupled to a selected row line RL among the plurality of pixels PX, into pixel values indicating light amounts, in response to the control signal from the timing generator 120.

The readout circuit 150 may convert pixel signals output through corresponding column lines CL into pixel values. For example, the readout circuit 150 may convert pixel signals into pixel values by comparing the pixel signals with ramp signals. Pixel values may be image data items, each of which has a plurality of bits. The readout circuit 150 may include a selector, a plurality of comparators, a plurality of counter circuits, etc.

The ramp signal generator 160 may generate a reference signal, and transmit the reference signal to the readout circuit 150. The ramp signal generator 160 may include current sources, resistors, and capacitors. The ramp signal generator 160 may adjust ramp voltage which is voltage to be applied to a ramp resistor by adjusting the current magnitudes of variable current sources or the resistance values of variable resistors. In this way, the ramp signal generator 160 may generate a plurality of ramp signals which fall or rise at slopes determined depending on the current magnitudes of variable current sources or the resistance values of variable resistors.

The data buffer 170 may store the pixel values of a plurality of pixels PX coupled to the selected column line CL, received from the readout circuit 150, and output the stored pixel values in response to an enable signal from the controller 110.

The image signal processor 180 may perform image signal processing on image signals received from the data buffer 170. For example, the image signal processor 180 may receive a plurality of image signals from the data buffer 170, and synthesize the received image signals to generate one image.

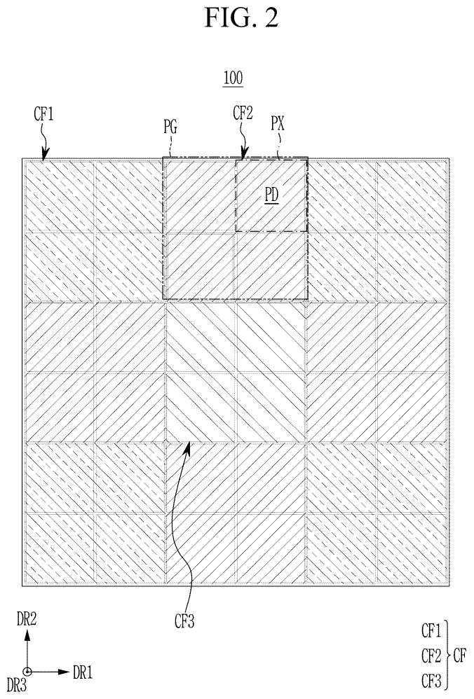

The pixel arrangement of the image sensor according to one or more embodiments will be described with reference to FIG. 2. FIG. 2 is a plan view illustrating a portion of an image sensor according to one or more embodiments.

The image sensor 100 according to one or more embodiments may include pixel groups PG, photodiode regions PD, color filters CF, and other circuits necessary for the operation of the image sensor 100.

Each of the plurality of pixels PX may include one photodiode region PD. Each photodiode region PD may include a photodiode, but embodiments are not limited thereto.

A plurality of pixels PX may be grouped in the form having a plurality of columns and a plurality of rows, thereby forming one unit pixel group PG.

A pixel group PG overlapping a first color filter CF1 may detect light of a first color, a pixel group PG overlapping a second color filter CF2 may detect light of a second color different from the first color, and a pixel group PG overlapping a third color filter CF3 may detect light of a third color different from the first color and the second color. According to one or more embodiments, the image sensor 100 may further include a pixel group for detecting all visible light.

Each of the plurality of pixel groups PG may include (N×M)-number of pixels in an N×M array. Each of N and M may independently be an integer greater than 1. For example, each of N and M may be 2 such that each pixel group may have a pixel array having a 2×2 tetra structure on a plane. In other words, each of the plurality of pixel groups PG may include pixels PX arranged in a 2×2 matrix on a plane.

More specifically, a plurality of pixels PX disposed in the arrangement direction of the column lines CL and a plurality of pixels PX disposed in the arrangement direction of the row lines RL may constitute one unit pixel group PG. For example, one unit pixel group PG may include a plurality of pixels PX arranged in a matrix having two columns and two rows, and one unit pixel group PG may output one analog pixel signal. However, embodiments are not limited thereto, and the number of pixels PX which are included in one pixel group PG may be variously changed.

The image sensor 100 according to one or more embodiments may further include micro lenses, and at least one micro lens may be positioned in each of the pixel groups PG.

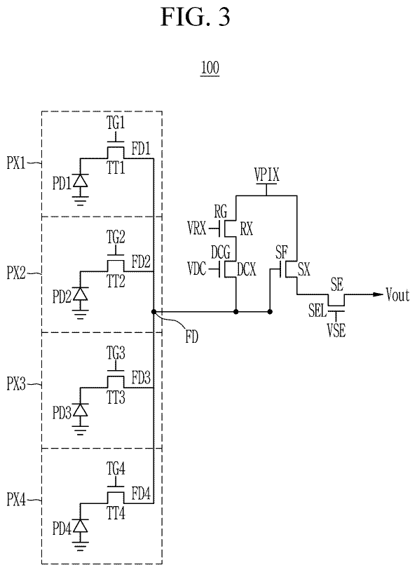

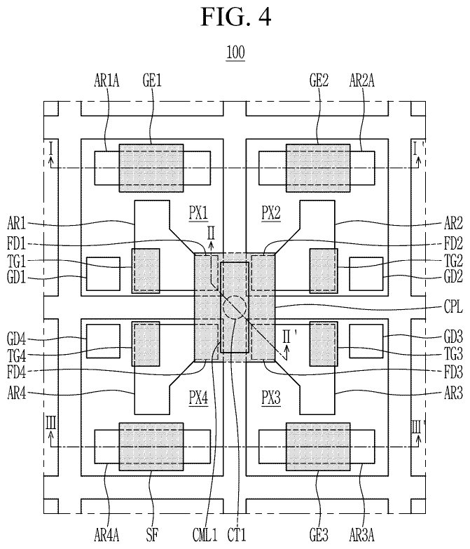

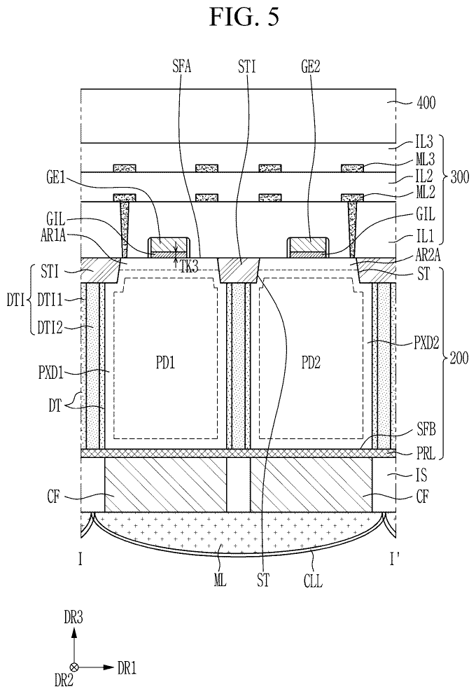

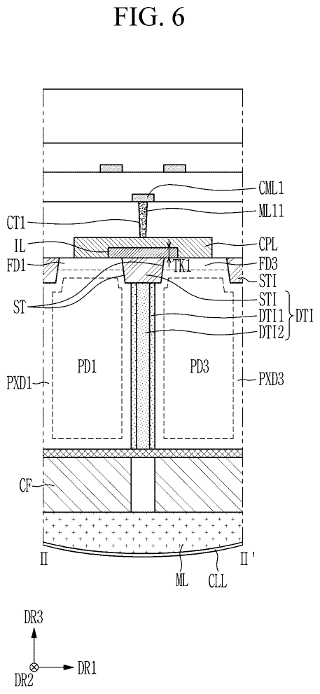

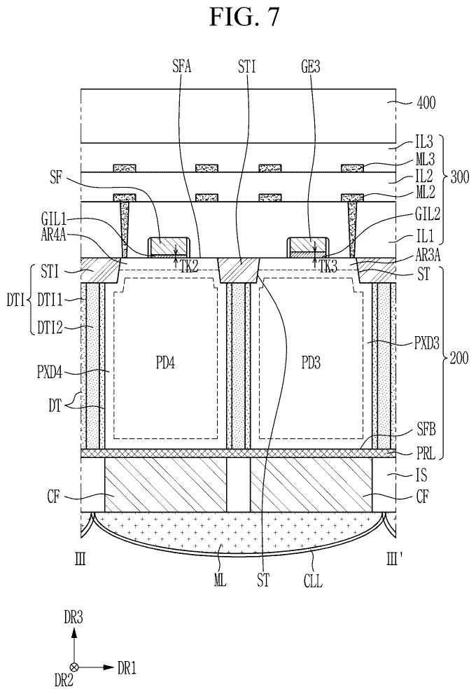

One pixel group of the image sensor according to one or more embodiments will be described with reference to FIGS. 3 to 7 together with FIG. 2. FIG. 3 is a diagram of an image sensor according to one or more embodiments, FIG. 4 is a plan view of an image sensor according to one or more embodiments, FIG. 5 is a cross-sectional view taken along line I-I′ of FIG. 4 according to one or more embodiments, FIG. 6 is a cross-sectional view taken along line II-II′ of FIG. 4 according to one or more embodiments, and FIG. 7 is a cross-sectional view taken along line III-III′ of FIG. 4 according to one or more embodiments.

Referring to FIG. 3 together with FIG. 2, a pixel group PG of the image sensor 100 according to one or more embodiments may include pixels PX1, PX2, PX3, and PX4, photodiode regions PD1, PD2, PD3, and PD4, transfer transistors TT1, TT2, TT3, and TT4, a reset transistor RX, a dual conversion gain transistor DCX, a source follower transistor SX, and a selection transistor SE. Although it is shown in the drawing that the pixel group PG includes four pixels PX1, PX2, PX3, and PX4 including photodiode regions PD1, PD2, PD3, and PD4 as described above, embodiments are not limited thereto.

The first pixel PX1 may include a first photodiode region PD1, the first transfer transistor TT1, and a first floating diffusion region FD1, the second pixel PX2 may include a second photodiode region PD2, the second transfer transistor TT2, and a second floating diffusion region FD2, the third pixel PX3 may include a third photodiode region PD3, the third transfer transistor TT3, and a third floating diffusion region FD3, and the fourth pixel PX4 may include a fourth photodiode region PD4, the fourth transfer transistor TT4, and a fourth floating diffusion region FD4.

The floating diffusion regions FD1, FD2, FD3, and FD4 of the pixels PX1, PX2, PX3, and PX4 may be connected to one another, and the pixels PX1, PX2, PX3, and PX4 may share a floating diffusion region FD including the floating diffusion regions FD1, FD2, FD3, and FD4.

The pixels PX1, PX2, PX3, and PX4 may share the reset transistor RX, the dual conversion gain transistor DCX, the source follower transistor SX, and the selection transistor SE.

The floating diffusion region FD may store charge corresponding to the amount of incident light.

While the transfer transistors TT1, TT2, TT3, and TT4 are individually turned on by transmission signals, the floating diffusion region FD may receive charge from the photodiode regions PD1, PD2, PD3, and PD4 and store the charge.

The reset transistor RX may be driven by a reset signal VRX, and may provide a power supply voltage to the floating diffusion region FD. As a result, the charge stored in the floating diffusion region FD may migrate to a power supply voltage (VPIX) terminal, and the voltage of the floating diffusion region FD may be reset.

The source follower transistor SX may be connected between a power supply voltage VPIX and the selection transistor SE. The source follower transistor SX may output an output signal Vout to the selection transistor SE on the basis of the voltage level of the floating diffusion region FD. The selection transistor SE may be driven by a selection signal VSE, and the output signal Vout may be output to the readout circuit 150 through a column line CL when the selection transistor SE is turned on.

The dual conversion gain transistor DCX may be connected between the floating diffusion region FD and the reset transistor RX. When the dual conversion gain transistor DCX is turned off by a dual conversion signal VDC, the full well capacity (FWC) of each of the pixels PX1, PX2, PX3, and PX4 may be the capacitance of the floating diffusion region FD. When the dual conversion gain transistor DCX is turned on by the dual conversion signal VDC, the full well capacity of each of the pixels PX1, PX2, PX3, and PX4 may become higher than the capacitance of the floating diffusion region FD. Based on whether the dual conversion gain transistor DCX is on or off, the conversion gain of each of the pixels PX1, PX2, PX3, and PX4 may vary.

The structure of the image sensor 100 according to one or more embodiments will be described in more detail with reference to FIGS. 4 to 7 together with FIGS. 2 and 3.

Referring to FIG. 4, the image sensor 100 according to one or more embodiments may include a pixel group PG including a first pixel PX1, a second pixel PX2, the third pixel PX3, and the fourth pixel PX4 disposed along a clockwise direction.

A photodiode isolation pattern DTI may be positioned so as to surround the edges of the photodiode regions the plurality of pixels PX1, PX2, PX3, and PX4. Also, the photodiode isolation pattern DTI may be positioned in at least some portions between the photodiode regions of the plurality of pixels PX1, PX2, PX3, and PX4.

The photodiode isolation pattern DTI may prevent cross-talk between the photodiode regions the plurality of pixels PX1, PX2, PX3, and PX4 adjacent to each other.

Referring to FIGS. 4 to 7, the image sensor 100 may include a substrate 200. The substrate 200 may contain silicon (Si), germanium (Ge), or silicon-germanium (Si-Ge). The substrate 200 may contain gallium arsenide (GaAs), indium phosphide (InP), gallium phosphide (GaP), indium arsenide (InAs), indium antimonide (InSb), or indium gallium arsenide (InGaAs). The substrate 200 may include zinc telluride (ZnTe) or cadmium sulfide (CdS).

The substrate 200 may be bulk silicon or a silicon-on-insulator (SOI). The substrate 200 may be a silicon substrate, or may include other materials, for example, silicon germanium, indium antimonide, a lead tellurium compound, indium arsenide, indium phosphide, gallium arsenide, or gallium antimonide. Alternatively, the substrate 200 may be a substrate made by forming an epitaxial layer on a base substrate.

The substrate 200 may be doped with an impurity of a first conductivity type. For example, the first conductivity type may be a p-type.

The substrate 200 may have a first surface SFA and a second surface SFB facing each other in the direction DR3.

The substrate 200 may include a deep trench DT, and the photodiode isolation pattern DTI may be positioned in the deep trench DT of the substrate 200.

As described above, the photodiode isolation pattern DTI may be positioned at the edges of the plurality of pixel regions PXD1, PXD2, PXD3, and PXD4 of the substrate 200, corresponding to the photodiode regions of the plurality of pixels PX1, PX2, PX3, and PX4 and in at least some portions between the photodiode regions of the plurality of pixel regions PXD1, PXD2, PXD3, and PXD4.

The deep trench DT and the photodiode isolation pattern DTI may pass through the substrate 200 from the first surface SFA to second surface SFB of the substrate 200.

The photodiode isolation pattern DTI may include a first pattern DTI1, a second pattern DTI2, and a shallow trench isolation pattern STI positioned inside a shallow trench ST. The first pattern DTI1 may cover the inner wall of the deep trench DT. The second pattern DTI2 may fill the lower portion of the deep trench DT. The shallow trench isolation pattern STI may be disposed on the first pattern DTI1 and the second pattern DTI2. In some embodiment, the first pattern DTI1 may be indistinguishable from the second pattern DTI2.

The second pattern DTI2 may be isolated from the substrate 200 by the first pattern DTI1 and the shallow trench isolation pattern STI.

The first pattern DTI1 and the shallow trench isolation pattern STI may contain silicon oxide, silicon nitride, and silicon oxynitride. The first pattern DTI1 may contain a metal oxide such as hafnium oxide, aluminum oxide, and tantalum oxide, and in this case, the first pattern DTI1 may act as a negative fixed charge layer. The second pattern DTI2 may contain a semiconductor material such as polysilicon doped into an n-type or a p-type.

The photodiode regions PD1, PD2, PD3, and PD4 may be positioned in the plurality of pixel regions PXD1, PXD2, PXD3, and PXD4 of the substrate 200 corresponding to the individual pixels PX1, PX2, PX3, and PX4.

Externally incident light may be converted into electrical signals in the photodiode regions PD1, PD2, PD3, and PD4. The photodiode regions PD1, PD2, PD3, and PD4 may include a photodiode positioned inside the substrate 200. The photodiode regions PD1, PD2, PD3, and PD4 may be doped with an impurity having a different conductive type from a conductive type of the impurity implanted into the substrate 200.

The photodiode regions PD1, PD2, PD3, and PD4 may be doped with an impurity of a second conductivity type different from the impurity of the first conductivity type implanted into the substrate 200. For example, the substrate 200 may be doped with a p-type impurity, and the photodiode regions PD1, PD2, PD3, and PD4 may be doped with an n-type impurity.

The n-type impurity regions of the photodiode regions PD1, PD2, PD3, and PD4 may form p-n junctions with the p-type impurity region of the substrate 200 around them, thereby constituting photodiodes, and when light enters there, electron-hole pairs may be generated by the p-n junctions.

In at least some portions between the photodiode regions PD1, PD2, PD3, and PD4 corresponding to the plurality of pixels PX1, PX2, PX3, and PX4, the photodiode isolation pattern DTI may be positioned such that the photodiode regions PD1, PD2, PD3, and PD4, corresponding to the plurality of pixels PX1, PX2, PX3, and PX4, respectively, may be isolated from each other in at least some portions by the photodiode isolation pattern DTI. The photodiode isolation pattern DTI may electrically and optically isolate the photodiode regions PD1, PD2, PD3, and PD4 adjacent to one another.

The substrate 200 may include the shallow trench ST, and the shallow trench isolation pattern STI may be positioned inside the shallow trench ST of the substrate 200. The shallow trench ST may be positioned in a portion of the substrate 200, without passing through the substrate 200 from the first surface SFA of the substrate 200. In a third direction DR3 which is the height direction, the depth of the shallow trench ST may be smaller than the depth of the deep trench DT. The shallow trench isolation pattern STI may contain silicon oxide, silicon nitride, or a combination thereof.

Alternatively, the shallow trench isolation pattern STI may be a region doped with an impurity of the same first conductivity type as that of the impurity implanted into the substrate 200 at a concentration higher than the doping concentration of the impurity implanted into the substrate 200.

The photodiode isolation pattern DTI may include the shallow trench isolation pattern STI. In one or more embodiments, the first pattern DTI1 may be connected to the shallow trench isolation pattern STI, and the shallow trench isolation pattern STI and the first pattern DTI1 may be indistinguishable from each other.

On the first surface SFA of the substrate 200, a plurality of gate electrodes TG1, TG2, TG3, TG4, GE1, GE2, GE3, and SF may be positioned.

The plurality of pixel regions PXD1, PXD2, PXD3, and PXD4 corresponding to the plurality of pixels PX1, PX2, PX3, and PX4 may include active regions AR1, AR2, AR3, AR4, AR1A, AR2A, AR3A, and AR4A positioned inside the substrate 200 so as to be adjacent to the first surface SFA of the substrate 200, respectively. The active regions AR1, AR2, AR3, AR4, AR1A, AR2A, AR3A, and AR4A may be isolated by the shallow trench isolation pattern STI.

The substrate 200 may include the floating diffusion regions FD1, FD2, FD3, and FD4 and ground regions GD1, GD2, GD3, and GD4 positioned adjacent to the first surface SFA.

The floating diffusion regions FD1, FD2, FD3, and FD4 may be adjacent to the transfer gate electrodes TG1, TG2, TG3, and TG4, respectively. The floating diffusion regions FD1, FD2, FD3, and FD4 may be doped with an impurity of the second conductivity type different from the impurity of the first conductivity type implanted into the substrate 200.

The ground regions GD1, GD2, GD3, and GD4 may be doped with the same conductive impurity as the conductive impurity implanted into the substrate 200, and the concentration of the implemented conductive impurity of the ground regions GD1, GD2, GD3, and GD4 may be higher than the concentration of the implemented conductive impurity in other regions of the substrate 200.

The active regions AR1, AR2, AR3, AR4, AR1A, AR2A, AR3A, and AR4A of the plurality of pixel regions PXD1, PXD2, PXD3, and PXD4 may be active regions for the operation of the plurality of transistors.

On the active regions AR1, AR2, AR3, AR4, AR1A, AR2A, AR3A, and AR4A, the plurality of gate electrodes TG1, TG2, TG3, TG4, GE1, GE2, GE3, and SF may be positioned.

The plurality of gate electrodes TG1, TG2, TG3, TG4, GE1, GE2, GE3, and SF and the floating diffusion region FD may form the transfer transistors TT1, TT2, TT3, and TT4, the source follower transistor SX, the selection transistor SE, the reset transistor RX, and the dual conversion gain transistor DCX. Among the plurality of gate electrodes TG1, TG2, TG3, TG4, GE1, GE2, GE3, and SF, the gate electrodes GE1, GE2, and GE3 may correspond to the gate electrodes SEL, RG, and DCG of the selection transistor SE, the reset transistor RX, and the dual conversion gain transistor DCX.

The ground regions GD1, GD2, GD3, and GD4 may be a ground pattern for grounding at least one of the transfer transistors TT1, TT2, TT3, and TT4, the selection transistor SE, the reset transistor RX, and the dual conversion gain transistor DCX.

On the first surface SFA of the substrate 200, a first structure 300 may be disposed. The first structure 300 may include a plurality of vias ML1 and ML11, a plurality of wiring layers ML2 and ML3, and a plurality of insulating layers IL1, IL2, and IL3. The plurality of insulating layers IL1, IL2, and IL3 may electrically isolate the plurality of vias ML1 and ML11 and the plurality of wiring layers ML2 and ML3.

The plurality of vias ML1 and ML11 and the plurality of wiring layers ML2 and ML3 may be electrically connected to the transistors on the first surface SFA of the substrate 200.

The plurality of vias ML1 and ML11 and the plurality of wiring layers ML2 and ML3 may contain tungsten, aluminum, copper, tungsten silicide, titanium silicide, tungsten nitride, titanium nitride, doped polysilicon, etc.

The plurality of insulating layers IL1, IL2, and IL3 may contain an insulating material such as silicon oxide, silicon nitride, silicon oxynitride, a low-dielectric constant (low-k) material, etc. The low-dielectric constant material may contain, for example, at least one of flowable oxide (FOX), torene silazene (TOSZ), undoped silica glass (USG), borosilica glass (BSG), phosphosilica glass (PSG), borophosphosilica glass (BPSG), plasma enhanced tetra-ethyl ortho silicate (PETEOS), fluoride silicate glass (FSG), carbon doped silicon oxide (CDO), xerogel, aerogel, amorphous fluorinated carbon, organo silicate glass (OSG), parylene, bis-benzocyclobutenes (BCB), SiLK, polyimide, porous polymeric materials, and combinations thereof.

The image sensor 100 may further include a support substrate 400 which is positioned on the first structure 300, but the support substrate 400 may be omitted. Between the support substrate 400 and the first structure 300, an adhesive member (not shown in the drawings) may be further positioned.

On the second surface SFB of the substrate 200, an antireflective layer PRL may be positioned. The antireflective layer PRL may cover the second surface SFB of the substrate 200 and the photodiode isolation pattern DTI.

The antireflective layer PRL may contain hafnium oxide (HfO₂), silicon oxide (SiO₂), silicon nitride (SIN), aluminum oxide (Al2O3), zirconium oxide (ZrO₂), tantalum oxide (Ta₂O₅), titanium oxide (TiO₂), lanthanum oxide (La₂O₃), praseodymium oxide (Pr203), cerium oxide (CeO2), neodymium oxide (Nd203), promethium oxide (Pm203), samarium oxide (Sm203), europium oxide (Eu203), gadolinium oxide (Gd203), terbium oxide (Tb203), dysprosium oxide (Dy203), holmium oxide (H0203), thulium oxide (Tm203), ytterbium oxide (Yb203), lutetium oxide (Lu2O3), yttrium oxide (Y₂O₃), or a combination thereof.

In one or more embodiments, the antireflective layer PRL may include a plurality of layers containing different materials and having different thicknesses. For example, the antireflective layer PRL may include a first antireflective layer to a third antireflective layer sequentially stacked on the second surface SFB of the substrate 200.

The first antireflective layer may be a fixed charge layer having negative fixed charge. Hole accumulation may occur around the fixed charge layer, whereby it is possible to effectively reduce occurrence of dark current and white spots.

The third antireflective layer may contain a metal oxide or a metal fluoride containing at least one of hafnium (Hf), zirconium (Zr), aluminum (Al), tantalum (Ta), titanium (Ti), and yttrium (Y). For example, the first antireflective layer and the third antireflective layer may include a hafnium oxide layer, and the second antireflective layer may contain silicon oxide and/or silicon nitride. However, in other embodiments, the number and relative thicknesses of layers constituting the antireflective layer PRL may be variously changed.

Also, in one or more embodiments, the antireflective layer PRL may further include a silicon nitride layer which is disposed between the second antireflective layer and the third antireflective layer.

Fence patterns IS may surround the color filters CF.

The fence patterns IS may contain a low-refractive-index material. The low-refractive-index material may have a refractive index larger than about 1.0 and equal to or smaller than about 1.4. For example, the low-refractive-index material may contain polymethylmetacrylate (PMMA), silicon acrylate, cellulose acetatebutyrate (CAB), silica, or fluoro-silicon acrylate (FSA). For example, the low-refractive-index material may contain a polymer material including silica (SiOx) particles dispersed therein.

When the fence patterns IS include a low-refractive-index material having a relatively low refractive index, incident light toward the fence patterns IS may be totally reflected, thereby being directed toward the center portion of each of the pixels PX1, PX2, PX3, and PX4.

The fence patterns IS may prevent light obliquely entering a color filter CF, disposed in one of the plurality of pixels PX1, PX2, PX3, and PX4, from entering another color filter CF disposed on an adjacent different photodiode region, thereby preventing cross-talk between the plurality of pixel PX1, PX2, PX3, and PX4.

The plurality of color filters CF may be disposed on the antireflective layer PRL, and isolated from one another by the fence pattern IS. The plurality of color filters CF may include, for example, a green filter, a blue filter, and a red filter. The plurality of color filters CF may include, for example, a cyan filter, a magenta filter, or a yellow filter.

A micro lens ML may be disposed on the color filters CF and the fence pattern IS.

The micro lens ML may be transparent. The micro lens ML may be formed on a resin-based material such as styrene-based resin, an acrylic resin, a styrene-acrylic copolymer resin, or a siloxane-based resin.

The micro lens ML may concentrate incident light, and the concentrated light may enter the photodiode regions PD1, PD2, PD3, and PD4 through the color filters CF.

A capping layer CLL may be disposed on the micro lens ML to protect the micro lens ML.

As shown in FIGS. 4 and 6, the first floating diffusion region FD1 which is positioned in the first pixel region PXD1, the second floating diffusion region FD2 which is positioned in the second pixel region PXD2, the third floating diffusion region FD3 which is positioned in the third pixel region PXD3, and the fourth floating diffusion region FD4 which is positioned in the fourth pixel region PXD4 may be connected to one another through a connection portion CPL. The first to fourth floating diffusion regions FD1, FD2, FD3, and FD4 may be connected to form the floating diffusion region FD.

The connection portion CPL may be positioned on the first surface SFA of the substrate 200. A portion of the connection portion CPL may be positioned on the photodiode isolation pattern DTI.

Other portions of the connection portion CPL may be positioned on the floating diffusion regions FD1, FD2, FD3, and FD4 and contact the floating diffusion regions FD1, FD2, FD3, and FD4.

Between a portion of the connection portion CPL and the first surface SFA of the substrate 200, an insulating pattern IL may be positioned. In a height direction DR3, a portion of the insulating pattern IL may overlap the photodiode isolation pattern DTI.

The insulating pattern IL may have a first thickness TK1.

The connection portion CPL of the floating diffusion regions FD1, FD2, FD3, and FD4 may contain, for example, at least one of polysilicon (poly-Si) doped with an impurity, metal silicides such as cobalt silicide, metal nitrides such as titanium nitride, and metals such as tungsten, copper, and aluminum, but embodiments are not limited thereto. For example, the connection portion CPL may include the same materials as other components, such as the plurality of gate electrodes TG1, TG2, TG3, TG4, GE1, GE2, GE3, and SF. For example, the plurality of gate electrodes TG1, TG2, TG3, TG4, GE1, GE2, GE3, and SF and the connection portion CPL may contain polysilicon doped with an impurity, and the plurality of gate electrodes TG1, TG2, TG3, TG4, GE1, GE2, GE3, and SF and the connection portion CPL may be formed together through the same process.

The connection portion CPL of the floating diffusion regions FD1, FD2, FD3, and FD4 may include the same material as at least one of the plurality of gate electrodes TG1, TG2, TG3, TG4, GE1, GE2, GE3, and SF, and may be formed together through the same process.

The connection portion CPL may be connected to a connection layer CML1 positioned on the insulating layer IL1 through the via ML11 positioned in a contact hole CT1 formed in the insulating layer IL1 positioned on the substrate 200. In the height direction DR3, the connection layer CML1 may be positioned at the same level as that of the wiring layer ML2. In the height direction DR3, the connection layer CML1 may overlap the photodiode isolation pattern DTI. The connection layer CML1 may be electrically connected to the source follower gate electrode SF of the source follower transistor SX. Through the connection layer CML1, the source follower gate electrode SF of the source follower transistor SX may be electrically connected to the floating diffusion regions FD1, FD2, FD3, and FD4.

Referring to FIGS. 4, 5, and 7, gate insulating layers GIL1 and GIL2 may be positioned between the plurality of gate electrodes TG1, TG2, TG3, TG4, GE1, GE2, GE3, and SF and the active regions AR1, AR2, AR3, AR4, AR1A, AR2A, AR3A, and AR4A of the substrate 200.

The first gate insulating layer GIL1 which is positioned between the source follower gate electrode SF and the active region AR4A may have a second thickness TK2.

Each of the second gate insulating layers GIL2 which are positioned between each of the gate electrodes TG1, TG2, TG3, TG4, GE1, GE2, and GE3 of the transfer transistors TT1, TT2, TT3, and TT4, the reset transistor RX, the dual conversion gain transistor DCX, and the selection transistor SE and each of the active regions AR1, AR2, AR3, AR4, AR1A, AR2A, and AR3A, may have a third thickness TK3.

The first thickness TK1 of the insulating pattern IL may be larger than the thicknesses TK2 and TK3 of the gate insulating layers GIL1 and GIL2.

The third thickness TK3 of each of the second gate insulating layers GIL2 may be larger than the second thickness TK2 of the first gate insulating layer GIL1.

According to one or more embodiments, the floating diffusion regions FD1, FD2, FD3, and FD4 may be connected to one another through the connection portion CPL which is positioned on the first surface SFA of the substrate 200 and in contact with the floating diffusion regions FD1, FD2, FD3, and FD4 and therefore the floating diffusion regions FD1, FD2, FD3, and FD4 may be connected to one another through a relatively shorter path as compared to the case where the floating diffusion regions FD1, FD2, FD3, and FD4 are connected to one another through the plurality of vias ML1 and the plurality of wiring layers ML2 and ML3 positioned in the plurality of insulating layers IL1, IL2, and IL3 positioned on the substrate 200. Accordingly, the connection resistance may be reduced and the operation characteristics of the image sensor may be improved.

According to one or more embodiments, the insulating pattern IL which is positioned between a portion of the connection portion CPL and the photodiode isolation pattern DTI may have the relatively large first thickness TK1, and therefore an influence of unnecessary coupling which may occur between the second pattern DTI2 of the photodiode isolation pattern DTI containing the doped polysilicon and the connection portion CPL containing the polysilicon doped with the impurity may be reduced, and short circuits which may be caused between the second pattern DTI2 of the photodiode isolation pattern DTI and the connection portion CPL by a process error may be prevented.

According to one or more embodiments, the gate insulating layers GIL1 and GIL2 and the insulating pattern IL, which are positioned below the gate electrodes TG1, TG2, TG3, TG4, GE1, GE2, GE3, and SF and the connection portion CPL which may be formed together through one process, may have different thicknesses, whereby it is possible to maintain the performance characteristics of the transistors TT1, TT2, TT3, TT4, RX, DCX, SE, and SX including the gate electrodes TG1, TG2, TG3, TG4, GE1, GE2, GE3, and SF while preventing unnecessary coupling and short circuits which may occur between the second pattern DTI2 of the photodiode isolation pattern DTI and the connection portion CPL. If the gate insulating layers GIL1 and GIL2 have the same first thickness TK1 as the insulating pattern IL, the gate insulating layers which are unnecessarily thick are positioned between the active regions AR1, AR2, AR3, AR4, AR1A, AR2A, AR3A, and AR4A and the gate electrodes TG1, TG2, TG3, TG4, GE1, GE2, GE3, and SF, whereby the on/off operation characteristics of the transistors TT1, TT2, TT3, TT4, RX, DCX, SE, and SX may be deteriorated.

According to one or more embodiments, the second thickness TK2 of the first gate insulating layer GIL1 which is positioned between the source follower gate electrode SF and the active region AR4A may be smaller than the third thickness TK3 of each of the second gate insulating layers GIL2 which are positioned between the gate electrodes TG1, TG2, TG3, TG4, GE1, GE2, and GE3 and the active regions AR1, AR2, AR3, AR4, AR1A, AR2A, and AR3A, and thereby the noise of the source follower transistor SX, which is relatively sensitive to the effects of thermal noise and flicker noise inherent to the transistor device, may be reduced.

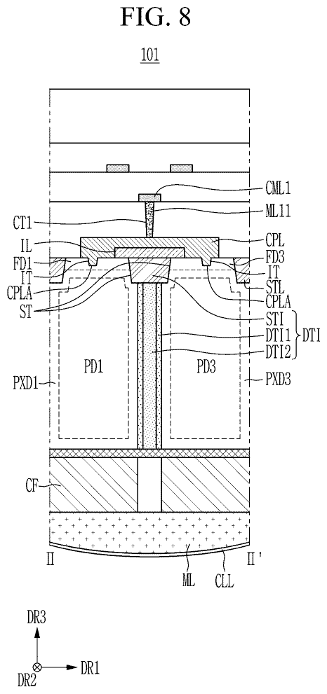

An image sensor according to one or more embodiments will be described with reference to FIG. 8.

FIG. 8 is a cross-sectional view illustrating an image sensor according to one or more embodiments. FIG. 8 is a cross-sectional view taken along line II-II′ of FIG. 4.

An image sensor 101 according to one or more embodiments is similar to the image sensor 100 and description of aspects that are the same as or similar to those described above may be omitted.

Referring to FIG. 8 together with FIG. 4, the floating diffusion regions FD1, FD2, FD3, and FD4 which are positioned adjacent to the first surface SFA of the substrate 200 may be connected to one another through the connection portion CPL which is positioned on the first surface SFA of the substrate 200 and contacts the floating diffusion regions FD1, FD2, FD3, and FD4.

In the image sensor 101 the connection portion CPL may further include extension portions CPLA extending into grooves IT formed in the floating diffusion regions FD1, FD2, FD3, and FD4 of the substrate 200.

According to one or more embodiments, the floating diffusion regions FD1, FD2, FD3, and FD4 may be connected to one another through the connection portion CPL which is positioned on the first surface SFA of the substrate 200 and contacting the floating diffusion regions FD1, FD2, FD3, and FD4, and therefore the floating diffusion regions FD1, FD2, FD3, and FD4 may be connected to one another through a relatively shorter path as compared to the case where the floating diffusion regions FD1, FD2, FD3, and FD4 are connected to one another through the plurality of vias ML1 and the plurality of wiring layers ML2 and ML3 positioned in the plurality of insulating layers IL1, IL2, and IL3 positioned on the substrate 200. Accordingly, the connection resistance may be reduced and the operation characteristics of the image sensor may be improved.

According to one or more embodiments, the connection portion CPL which connects the floating diffusion regions FD1, FD2, FD3, and FD4 may further include extension portions CPLA extending into grooves IT formed in the floating diffusion regions FD1, FD2, FD3, and FD4 of the substrate 200 such that the contact area between the connection portion CPL and the floating diffusion regions FD1, FD2, FD3, and FD4 increases, whereby the contact characteristic between the connection portion CPL and the floating diffusion regions FD1, FD2, FD3, and FD4 may be improved, resulting in a decrease in the resistance.

According to one or more embodiments, the insulating pattern IL which is positioned between a portion of the connection portion CPL and the photodiode isolation pattern DTI may have the relatively large first thickness TK1, whereby unnecessary coupling which may occur between the second pattern DTI2 of the photodiode isolation pattern DTI containing the doped polysilicon and the connection portion CPL containing the polysilicon doped with the impurity may be prevented, and short circuits which may be caused between the second pattern DTI2 of the photodiode isolation pattern DTI and the connection portion CPL by a process error may be prevented.

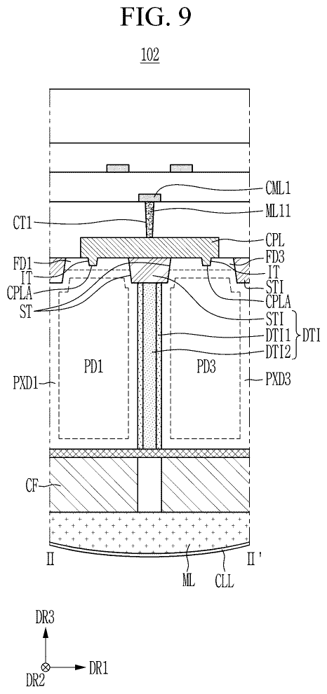

An image sensor according to one or more embodiments will be described with reference to FIG. 9. FIG. 9 is a cross-sectional view illustrating an image sensor according to one or more embodiments. FIG. 9 is a cross-sectional view taken along line II-II′ of FIG. 4.

Referring to FIG. 9 together with FIG. 4, the floating diffusion regions FD1, FD2, FD3, and FD4 which are positioned adjacent to the first surface SFA of the substrate 200 may be connected to one another through the connection portion CPL which is positioned on the first surface SFA of the substrate 200 and abuts the floating diffusion regions FD1, FD2, FD3, and FD4.

In the image sensor 102, the connection portion CPL may further include extension portions CPLA extending into grooves IT formed in the floating diffusion regions FD1, FD2, FD3, and FD4 of the substrate 200.

In the image sensor 102, the insulating pattern IL which is positioned between a portion of the connection portion CPL and the photodiode isolation pattern DTI may be omitted so that the contact area between the connection portion CPL and the floating diffusion regions FD1, FD2, FD3, and FD4 increases. Accordingly, the contact characteristic between the connection portion CPL and the floating diffusion regions FD1, FD2, FD3, and FD4 may be improved, resulting in a decrease in the resistance.

According to one or more embodiments, the floating diffusion regions FD1, FD2, FD3, and FD4 may be connected to one another through the connection portion CPL which is positioned on the first surface SFA of the substrate 200 and contacting the floating diffusion regions FD1, FD2, FD3, and FD4 and therefore the floating diffusion regions FD1, FD2, FD3, and FD4 may be connected to one another through a relatively shorter path as compared to the case where the floating diffusion regions FD1, FD2, FD3, and FD4 are connected to one another through the plurality of vias ML1 and the plurality of wiring layers ML2 and ML3 positioned in the plurality of insulating layers IL1, IL2, and IL3 positioned on the substrate 200. Accordingly, the connection resistance may be reduced and the operation characteristics of the image sensor may be improved.

According to one or more embodiments, the connection portion CPL which connects the floating diffusion regions FD1, FD2, FD3, and FD4 may further include extension portions CPLA extending into grooves IT formed in the floating diffusion regions FD1, FD2, FD3, and FD4 of the substrate 200 such that the contact area between the connection portion CPL and the floating diffusion regions FD1, FD2, FD3, and FD4 increases, whereby the contact characteristic between the connection portion CPL and the floating diffusion regions FD1, FD2, FD3, and FD4 may be improved, resulting in a decrease in the resistance.

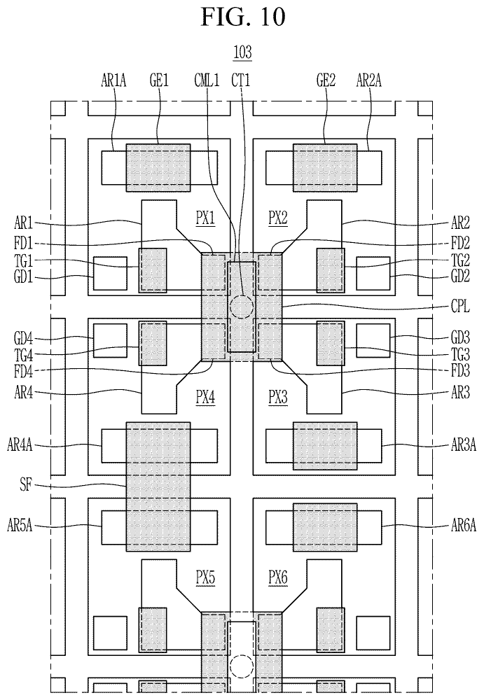

An image sensor according to one or more embodiments will be described with reference to FIG. 10. FIG. 10 is a plan view of an image sensor according to one or more embodiments.

Referring to FIG. 10, an image sensor 103 according to one or more embodiments is similar to the image sensor 100 and description of aspects that are the same as or similar to those described above may be omitted.

The floating diffusion regions FD1, FD2, FD3, and FD4 of the pixels PX1, PX2, PX3, and PX4 may be connected to one another through a connection portion CPL. The connection portion CPL may be similar to those in the image sensors 100, 101, and 102 according to one or more embodiments described with reference to FIGS. 6, 8, and 9.

Referring to FIG. 10, the image sensor 103 may further include pixels PX5 and PX6 adjacent to the pixels PX1, PX2, PX3, and PX4. The source follower gate electrode SF of the source follower transistor SX of the pixels PX1, PX2, PX3, and PX4 which form one pixel group PG may be formed integrally with the source follower gate electrode SF of the pixels PX5 and PX6 of the adjacent pixel group PG. Therefore, the source follower transistor SX may include a first source follower transistor and a second source follower transistor which are positioned in the third pixel PX3 and the fifth pixel PX5, respectively, and are connected to each other, and the two adjacent pixel groups may share the first source follower transistor and the second source follower transistor.

The source follower transistor may be most sensitive to the influence of thermal noise and flicker noise intrinsic to the transistor element than other transistors such as the transfer transistors, the reset transistor, and the selection transistor. Noise caused by the source follower transistor is directly transferred to the internal circuit, resulting in deterioration in the image quality. According to one or more embodiments, the source follower transistor includes the first source follower transistor and the second source follower transistor positioned in the adjacent pixel groups and is shared, thereby the influence of thermal noise and flicker noise intrinsic to the source follower transistor element may be reduced, and the amount of current during the operation of the source follower transistor may be increased. Accordingly, the linearity of the voltage-current graph of the source follower transistor may be improved, and noise of the source follower transistor may be reduced.

The floating diffusion regions FD1, FD2, FD3, and FD4 may be connected to one another through the connection portion CPL abutting the floating diffusion regions FD1, FD2, FD3, and FD4 and therefore the floating diffusion regions FD1, FD2, FD3, and FD4 are connected to one another through a relatively shorter path as compared to the case where the floating diffusion regions FD1, FD2, FD3, and FD4 are connected to one another through the plurality of vias ML1 and the plurality of wiring layers ML2 and ML3 positioned in the plurality of insulating layers IL1, IL2, and IL3 positioned on the substrate 200. Accordingly, the connection resistance may be reduced and the operation characteristics of the image sensor may be improved.

The insulating pattern IL which is positioned between a portion of the connection portion CPL and the photodiode isolation pattern DTI may have the relatively large first thickness TK1, whereby unnecessary coupling which may occur between the second pattern DTI2 of the photodiode isolation pattern DTI containing the doped polysilicon and the connection portion CPL containing the polysilicon doped with the impurity may be prevented, and short circuits which may be caused between the second pattern DTI2 of the photodiode isolation pattern DTI and the connection portion CPL by a process error may be prevented.

The gate insulating layers GIL1 and GIL2 and the insulating pattern IL, which are positioned below the gate electrodes TG1, TG2, TG3, TG4, GE1, GE2, GE3, and SF and the connection portion CPL which may be formed together through one process, may have different thicknesses, whereby it is possible to maintain the performance characteristics of the transistors TT1, TT2, TT3, TT4, RX, DCX, SE, and SX including the gate electrodes TG1, TG2, TG3, TG4, GE1, GE2, GE3, and SF while preventing unnecessary coupling and short circuits which may occur between the second pattern DTI2 of the photodiode isolation pattern DTI and the connection portion CPL.

The second thickness TK2 of the first gate insulating layer GIL1 which is positioned between the source follower gate electrode SF and the active region AR4A may be smaller than the third thickness TK3 of each of the second gate insulating layers GIL2 which are positioned between the gate electrodes TG1, TG2, TG3, TG4, GE1, GE2, and GE3 and the active regions AR1, AR2, AR3, AR4, AR1A, AR2A, and AR3A, whereby noise of the source follower transistor SX relatively sensitive to the influence of thermal noise and flicker noise intrinsic to the transistor elements may be reduced.

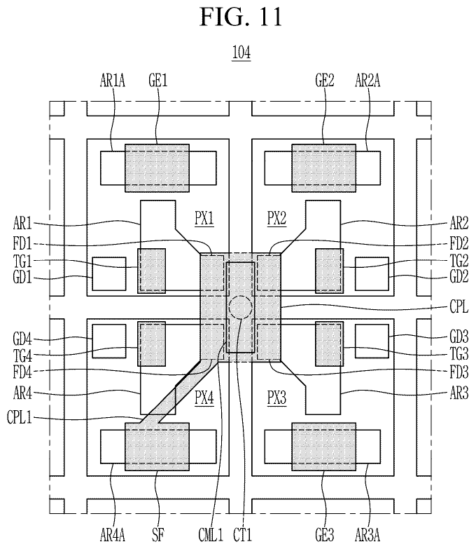

An image sensor according to one or more embodiments will be described with reference to FIG. 11. FIG. 11 is a plan view of an image sensor according to one or more embodiments.

Referring to FIG. 11, an image sensor 104 according to one or more embodiments is similar to the image sensor 100 and description of aspects that are the same as or similar to those described above may be omitted.

The floating diffusion regions FD1, FD2, FD3, and FD4 of the pixels PX1, PX2, PX3, and PX4 may be connected to one another through a connection portion CPL. The connection portion CPL may be similar to those in the image sensors 100, 101, and 102 according to one or more embodiments described with reference to FIGS. 6, 8, and 9.

Referring to FIG. 11, the connection portion CPL of the image sensor 104 may further include an extension connection portion CPL1 extending to the source follower gate electrode SF.

The connection portion CPL may connect the floating diffusion regions FD1, FD2, FD3, and FD4 to one another, and connect the floating diffusion regions FD1, FD2, FD3, and FD4 and the source follower gate electrode SF to each other through the extension connection portion CPL1 extending from the connection portion CPL.

The insulating pattern IL may be positioned not only below the connection portion CPL but also below the extension connection portion CPL1. The extension connection portion CPL1 and the substrate 200 may be insulated from each other through the insulating pattern IL positioned below the extension connection portion CPL1. Accordingly, the extension connection portion CPL1 may be positioned not only on a region where any transistor is not positioned, for example, a region where the photodiode isolation pattern DTI and/or the shallow trench isolation pattern STI is positioned, but also on a region overlapping an active region SR4. Therefore, the degree of freedom in designing a connection path for connecting the floating diffusion regions FD1, FD2, FD3, and FD4 and the source follower gate electrode SF may be increased, and the connection path may be shortened, resulting in an improvement in the performance of the source follower transistor SX.

The floating diffusion regions FD1, FD2, FD3, and FD4 may be connected to one another through the connection portion CPL abutting the floating diffusion regions FD1, FD2, FD3, and FD4 whereby the floating diffusion regions FD1, FD2, FD3, and FD4 are connected to one another through a relatively shorter path as compared to the case where the floating diffusion regions FD1, FD2, FD3, and FD4 are connected to one another through the plurality of vias ML1 and the plurality of wiring layers ML2 and ML3 positioned in the plurality of insulating layers IL1, IL2, and IL3 positioned on the substrate 200. Accordingly, the connection resistance may be reduced and the operation characteristics of the image sensor may be improved.

The insulating pattern IL which is positioned between a portion of the connection portion CPL and the photodiode isolation pattern DTI may have the relatively large first thickness TK1, whereby unnecessary coupling which may occur between the second pattern DTI2 of the photodiode isolation pattern DTI containing the doped polysilicon and the connection portion CPL containing the polysilicon doped with the impurity may be prevented, and short circuits which may be caused between the second pattern DTI2 of the photodiode isolation pattern DTI and the connection portion CPL by a process error may be prevented.

The gate insulating layers GIL1 and GIL2 and the insulating pattern IL, which are positioned below the gate electrodes TG1, TG2, TG3, TG4, GE1, GE2, GE3, and SF and the connection portion CPL which may be formed together through one process, may have different thicknesses, whereby it is possible to maintain the performance characteristics of the transistors TT1, TT2, TT3, TT4, RX, DCX, SE, and SX including the gate electrodes TG1, TG2, TG3, TG4, GE1, GE2, GE3, and SF while preventing unnecessary coupling and short circuits which may occur between the second pattern DTI2 of the photodiode isolation pattern DTI and the connection portion CPL.

The second thickness TK2 of the first gate insulating layer GIL1 which is positioned between the source follower gate electrode SF and the active region AR4A may be smaller than the third thickness TK3 of each of the second gate insulating layers GIL2 which are positioned between the gate electrodes TG1, TG2, TG3, TG4, GE1, GE2, and GE3 and the active regions AR1, AR2, AR3, AR4, AR1A, AR2A, and AR3A, whereby noise of the source follower transistor SX relatively sensitive to the influence of thermal noise and flicker noise intrinsic to the transistor elements may be reduced.

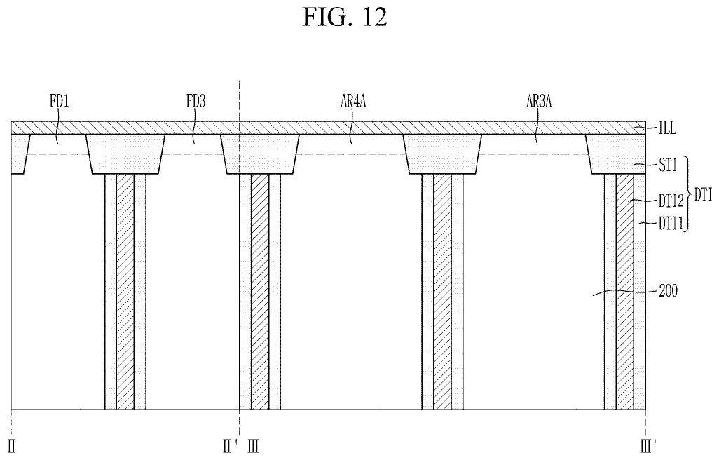

A method of manufacturing the image sensor according to one or more embodiments will be described with reference to FIGS. 12 to 19. FIGS. 12 to 19 are cross-sectional views illustrating a method of manufacturing an image sensor according to one or more embodiments. FIGS. 12 to 19 are cross-sectional views taken along line Il′-Il′ and line III-IlI′ of FIG. 4.

Referring to FIG. 12, an insulating layer ILL may be stacked on a substrate 200.

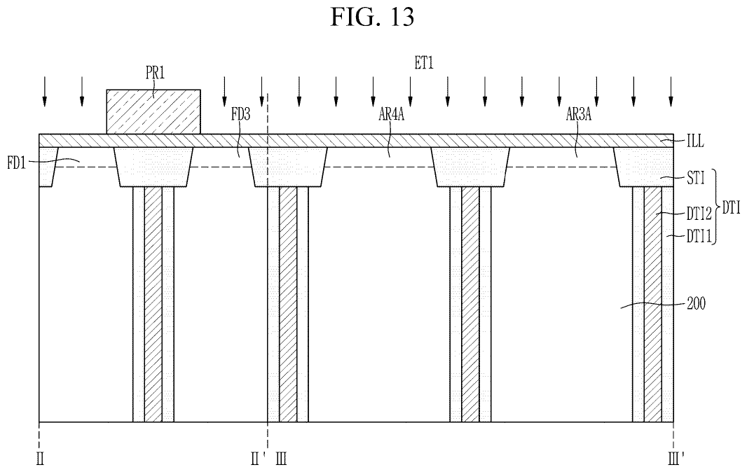

Referring to FIG. 13, an etching mask pattern PR1 may be formed at a position where the connection portion CPL of the image sensors 100, 101, 102, 103, and 104 and the extension connection portion CPL1 of the image sensor 104 will be formed, and etching ET1 may be performed on the insulating layer ILL.

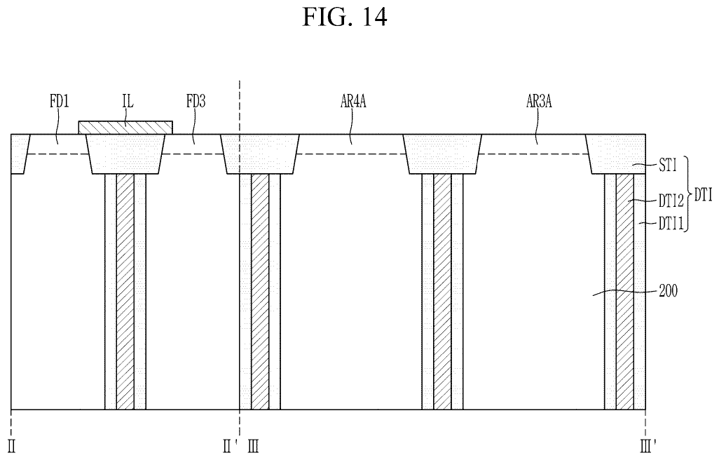

Referring to FIG. 14, the insulating pattern IL may be formed at the position where the connection portion CPL of the image sensors 100, 101, 102, 103, and 104 and the extension connection portion CPL1 of the image sensor 104 will be formed.

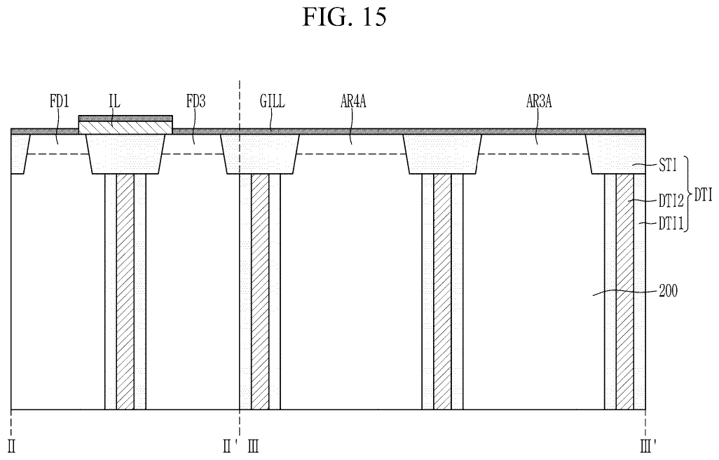

Referring to FIG. 15, on the substrate 200 with the insulating pattern IL formed thereon, an insulating layer GILL may be stacked.

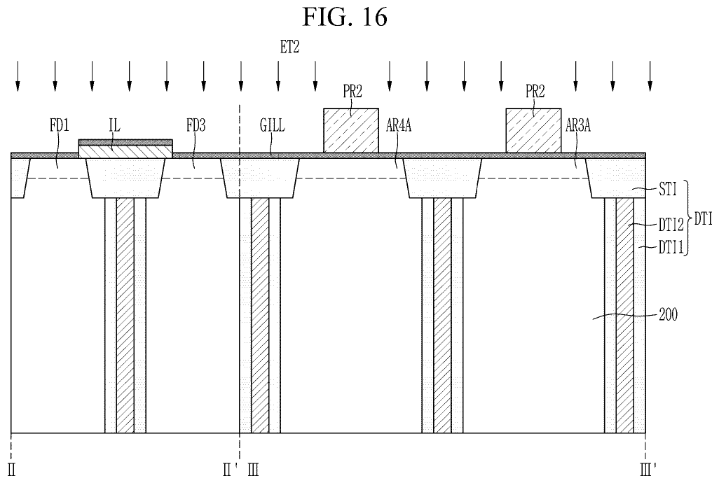

Referring to FIG. 16, an etching mask pattern PR2 may be formed at a position where gate electrodes TG1, TG2, TG3, TG4, GE1, GE2, GE3, and SF will be formed, and etching ET2 may be performed on the insulating layer GILL.

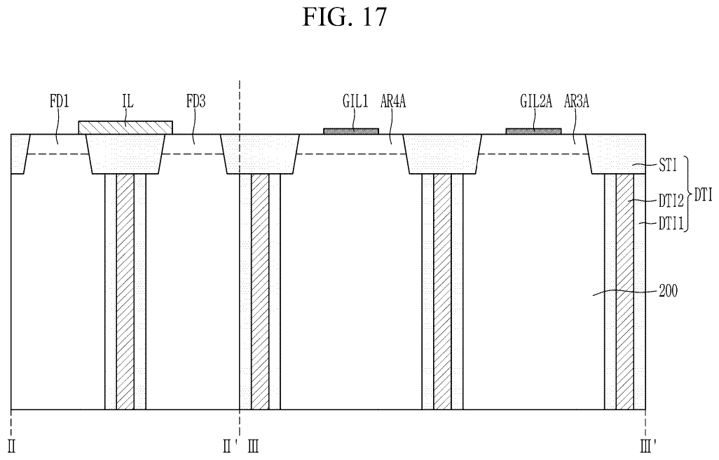

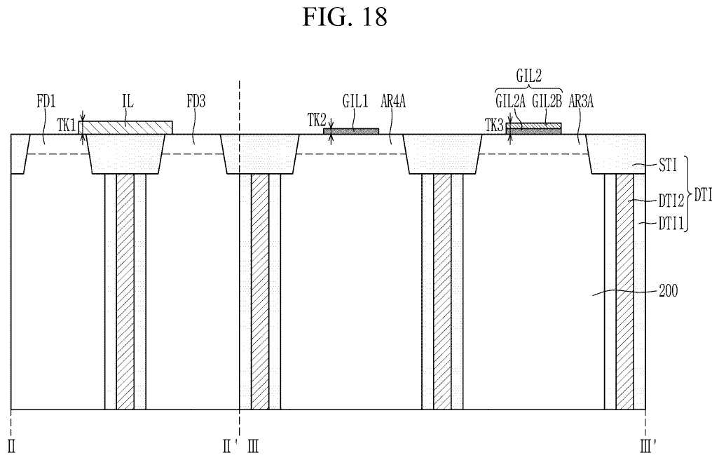

Referring to FIG. 17, a first gate insulating layer GIL1 and a lower layer GIL2A of a second gate insulating layer GIL2 (as shown in FIG. 18) may be formed at a position where the gate electrodes TG1, TG2, TG3, TG4, GE1, GE2, GE3, and SF will be formed.

Referring to FIG. 18, on the lower layer GIL2A of the second gate insulating layer GIL2, an upper layer GIL2B of the second gate insulating layers GIL2 may be formed. In this case, at the position where the gate electrode SF will be formed, the upper layer may not be formed.

The insulating pattern IL which is positioned below the connection portion CPL and the extension connection portion CPL1 may have a first thickness TK1, the first gate insulating layer GIL1 which is positioned below the source follower gate electrode SF may have a second thickness TK2, and each of the second gate insulating layers GIL2 which are positioned below the other gate electrodes TG1, TG2, TG3, TG4, GE1, GE2, and GE3 and include the lower layer GIL2A and the upper layer GIL2B may have a third thickness TK3.

The first thickness TK1 of the insulating pattern IL may be larger than the thicknesses TK2 and TK3 of the gate insulating layers GIL1 and GIL2, and the third thickness TK3 of each of the second gate insulating layers GIL2 may be larger than the second thickness TK2 of the first gate insulating layer GIL1.

Thus, the insulating pattern IL, the first gate insulating layer GIL1, and the second gate insulating layers GIL2, which have different thicknesses, may be formed.

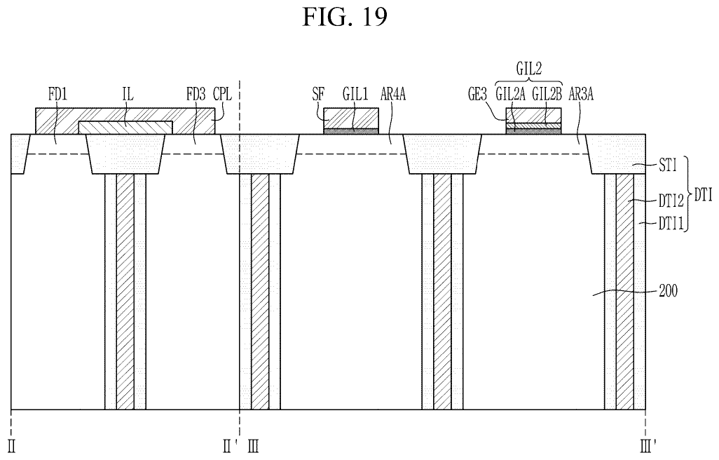

Referring to FIG. 19, on the insulating pattern IL and the floating diffusion regions FD1, FD2, FD3, and FD4, a connection portion CPL may be formed, and on the first gate insulating layer GIL1, a source follower gate electrode SF may be formed, and on the second gate insulating layers GIL2, the gate electrodes TG1, TG2, TG3, TG4, GE1, GE2, and GE3 may be formed. In this case, according to one or more embodiments, an extension connection portion CPL1 may be formed on the insulating pattern IL.

According to one or more embodiments, after grooves IT are formed in floating diffusion regions FD1, FD2, FD3, and FD4, a connection portion CPL which includes extension portions CPLA extending into the grooves IT may be formed.

Thereafter, on the first surface SFA of the substrate 200, the first structure 300 and the support substrate 400 may be formed, and on the second surface SFB of the substrate 200, the antireflective layer PRL, fence patterns IS, color filters CF, micro lenses ML, and the capping layer CLL may be formed, whereby the image sensor 100 may be formed.

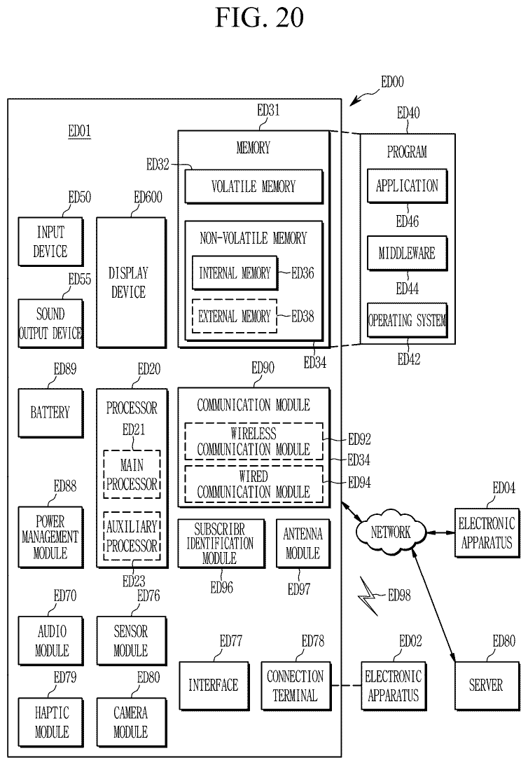

An electronic apparatus including an image sensor according to one or more embodiments will be described with reference to FIG. 20. FIG. 20 is a block diagram illustrating an example of an electronic apparatus including an image sensor according to one or more embodiments.

Referring to FIG. 20, an electronic apparatus ED01 according to one or more embodiments may include a processor ED20, a memory ED30, an input device ED50, a sound output device ED55, a display device ED60, an audio module ED70, a sensor module ED76, an interface ED77, a haptic module ED79, a camera module ED80, a power management module ED88, a battery ED89, a communication module ED90, a subscriber identification module ED96, and/or an antenna module ED97. According to one or more embodiments, some of the constituent elements of the electronic apparatus ED01, for example, the display device ED60 and so on, may be omitted. According to one or more embodiments, some of the constituent elements of the electronic apparatus ED01 may be implemented as one integrated circuit. For example, the sensor module ED76 (such as a fingerprint sensor, an iris sensor, an illuminance sensor, etc.) may be embedded in the display device ED60.

In a network environment ED00, the electronic apparatus ED01 may perform communication with another electronic apparatus ED02 through a first network ED98 (such as a short-distance radio communication network), or may perform communication with a further electronic apparatus ED04 and/or a server ED08 through a second network ED99 (such as a long-distance radio communication network). The electronic apparatus ED01 may perform communication with the electronic apparatus ED04 through the server ED08.

The processor ED20 may control one constituent element or a plurality of different constituent elements of the electronic apparatus ED01 connected to the processor ED20, such as hardware or software constituent elements, by executing software such as a program ED40, and may perform various data processing or computation. As part of the data processing or computation, the processor ED20 may load commands and/or data, received from other constituent elements, for example, the sensor module ED76 and/or the communication module ED90, etc., in a memory ED31 such as the volatile memory ED32, process the commands and/or the data stored in the volatile memory ED32, and store the result data in a non-volatile memory ED34.

The processor ED20 may include a main processor ED21 such as a central processing unit or an application processor, and an auxiliary processor ED23 which may be operated independently from or together with the main processor, such as a graphic processing unit, an image signal processor, a sensor hub processor, a communication processor, etc. The auxiliary processor ED23 may use less power than the main processor ED21 and perform a specialized function.

The auxiliary processor ED23 may control functions and/or states related to some constituent elements of the constituent elements of the electronic apparatus ED01, such as the display device ED60, the sensor module ED76, the communication module ED90, etc., in place of the main processor ED21 while the main processor ED21 is in the inactive state (the sleep state), or together with the main processor ED21 while the main processor ED21 is in the active state (the application execution state). The auxiliary processor ED23 such as the image signal processor, the communication processor may be implemented as a part of the camera module ED80 or the communication module ED90 which is another functionally related constituent element.

The memory ED30 may store a variety of data which is required by the processor ED20, the sensor module ED76, and so on of the constituent elements of the electronic apparatus ED01. The data may include, for example, software such as the program ED40, and input data and/or output data of commands related to the software. The memory ED30 may include the volatile memory ED32 and/or the non-volatile memory ED34.

The program ED40 may be stored as software in the memory ED30, and may include an operating system ED42, middleware ED44, and/or an application ED46.

The input device ED50 may receive commands and/or data to be used in the processor ED20 and so on of the electronic apparatus ED01, from the outside of the electronic apparatus ED01 (such as a user). The input device ED50 may include a microphone, a mouse, a keyboard, and/or a digital pen (such as a stylus pen).

The sound output device ED55 may output a sound signal to the outside of the electronic apparatus ED01. The sound output device ED55 may include a speaker and/or a receiver. The speaker may be used for general purposes, such as playing multimedia or playing records, and the receiver may be used to receive incoming calls. The receiver may be combined as a part of the speaker, or may be implemented as an independent separate device.

The display device ED60 may visually provide information to the outside of the electronic apparatus ED01. The display device ED60 may include a display, a hologram device, or a projector, and a control circuit for controlling the corresponding device. The display device ED60 may include touch circuitry set to detect a touch, and/or sensor circuitry (such as a pressure sensor) set to measure the intensity of a force generated by a touch.

The audio module ED70 may convert sound into an electrical signal or conversely convert an electrical signal into sound. The audio module ED70 may obtain sound through the input device ED50, or output sound through the sound output device ED55, and/or a speaker and/or a headphone of another electronic apparatus (such as the electronic apparatus ED02) directly or wirelessly connected to the electronic apparatus ED01.

The sensor module ED76 may detect the operating state of the electronic apparatus ED01 (such as power, temperature, etc.) or the external environment state (such as the user state), and generate an electrical signal and/or a data value corresponding to the detected state. The sensor module ED76 may include a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, and/or an illuminance sensor.

The interface ED77 may support one or more designated protocols which may be used for the electronic apparatus ED01 to be directly or wirelessly connected to another electronic apparatus (such as the electronic apparatus ED02). The interface ED77 may include a high definition multimedia interface (HDMI), a universal serial bus (USB) interface, a secure digital (SD) card interface, and/or an audio interface.

A connection terminal ED78 may include a connector through which the electronic apparatus ED01 may be physically connected to another electronic apparatus (such as the electronic apparatus ED02). The connection terminal ED78 may include a HDMI connector, a USB connector, a SD card connector, and/or an audio connector (such as a headphone connector).

The haptic module ED79 may convert an electrical signal into a mechanical stimulus (such as vibration or motion) or an electrical stimulus which may be recognized by a user via their tactile sensation or kinesthetic sensation. The haptic module ED79 may include a motor, a piezoelectric element, and/or an electric stimulator.

The camera module ED80 may capture still images and videos. The camera module ED80 may include a lens assembly including one or more lenses, the above-described image sensors 100, 101, 102, 103, and 104, image signal processors, and/or flashes. The lens assembly included in the camera module ED80 may collect light emitted from a subject which is the object of image capturing.

The power management module ED88 may manage power supplied to the electronic apparatus ED01. The power management module ED88 may be implemented as a part of a power management integrated circuit (PMIC).

The battery ED89 may supply power to the constituent elements of the electronic apparatus ED01. The battery ED89 may include a primary battery which is not rechargeable, a secondary battery which is rechargeable, and/or a fuel cell.

The communication module ED90 may support establishing a direct (wired) communication channel and/or wireless communication channel between the electronic apparatus ED01 and another electronic apparatus (the electronic apparatus ED02, the electronic apparatus ED04, the server ED08, etc.), and performing communication through the established communication channel. The communication module ED90 may include one or more communication processors which are operated independently from the processor ED20 (such as the application processor) and support direct communication and/or wireless communication. The communication module ED90 may include a wireless communication module ED92 (such as a cellular communication module, a short-distance wireless communication module, a global navigation satellite system (GNSS) communication module, etc.) and/or a wired communication module ED94 (such as a local area network (LAN) communication module, a power line communication module, etc.). Among these communication modules, a corresponding communication module may perform communication with another electronic apparatus through the first network ED98 (a short-distance communication network such as Bluetooth, Wi-Fi direct or infrared data association (IrDA)) or the second network ED99 (a long-distance communication network such as a cellular network, the Internet, or a computer network (e.g., a LAN, a WAN, etc.). These various types of communication modules may be integrated into one constituent element (such as a single chip), or may be implemented as a plurality of separate constituent elements (multiple chips). The wireless communication module ED92 may identify and authenticate the electronic apparatus ED01 in a communication network such as the first network ED98 and/or the second network ED99, using subscriber information (such as international mobile subscriber identity (IMSI)) stored in the subscriber identification module ED96.

The antenna module ED97 may transmit or receive a signal and/or power to or from the outside (such as another electronic apparatus).

The antenna module may include a radiator formed in a conductive pattern on a substrate (such as a printed circuit board (PCB)). The antenna module ED97 may include one or more antennae. When a plurality of antennae is included, an antenna appropriate for a communication scheme which is used in the communication network such as the first network ED98 and/or the second network ED99 may be selected from the plurality of antennae by the communication module ED90. Through the selected antenna, a signal and/or power may be transmitted or received between the communication module ED90 and another electronic apparatus. Besides the antenna, other components (such as a radio frequency integrated circuit (RFIC)) may be included as parts of the antenna module ED97.

Some of the constituent elements may be mutually connected and mutually exchange signals (such as commands, data, etc.) through an inter-peripheral communication scheme (such as a bus, general purpose input and output (GPIO), a serial peripheral interface (SPI), or a mobile industry processor interface (MIPI)).

Commands or data may be transmitted or received between the electronic apparatus ED01 and the external electronic apparatus ED04 through the server ED08 connected to the second network ED99. The other electronic apparatuses ED02 and ED04 may be devices of the same type as or a different type from the electronic apparatus ED01. All or some of operations which are performed in the electronic apparatus ED01 may be performed in one or more devices of the other electronic apparatuses ED02, ED04, and ED08. For example, when the electronic apparatus ED01 should perform a function or a service, the electronic apparatus may request one or more other electronic apparatuses to perform a part or all of the function or the service, instead of performing the function or the service by itself. The one or more other electronic apparatuses receiving the request may perform an additional function or service related to the request, and transmit the performance result to the electronic apparatus ED01. To that end, cloud computing, distributed computing, and/or client-server computing technology may be used.

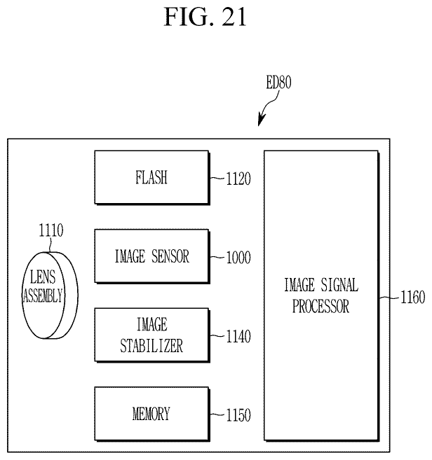

The camera module including the image sensor according to one or more embodiments will be described with reference to FIG. 21. FIG. 21 is a block diagram of an example of the camera module included in an electronic apparatus (e.g., the apparatus of FIG. 20) according to one or more embodiments.

Referring to FIG. 21, the camera module ED80 may include a lens assembly 1110, a flash 1120, an image sensor 1000, an image stabilizer 1140, a memory 1150 (such as a buffer memory), and/or an image signal processor 1160. The lens assembly 1110 may collect light emitted from a subject which is an object of image capturing. The camera module ED80 may include a plurality of lens assemblies 1110, and in this case, the camera module ED80 may form a dual camera, a 360-degree camera, or a spherical camera. Some of the plurality of lens assemblies 1110 may have the same lens attribute (such as view angle, focal length, auto-focusing, F number, optical zoom, etc.), or may have different lens attributes. The lens assembly 1110 may include a wide-angle lens or a telephoto lens.

The flash 1120 may emit light to be used to reinforce light emitted or reflected from the subject. The flash 1120 may emit visible light or infrared light. The flash 1120 may include one or more light emitting diodes (such as a red-green-blue (RGB) light emitting diode (LED), a white LED, an infrared LED, an ultraviolet LED, etc.), and/or a xenon lamp. The image sensor 1000 may be one of the image sensors 100, 101, 102, 103, and 104, and convert light, emitted or reflected from the subject and received through the lens assembly 1110, into an electrical signal, thereby obtaining an image corresponding to the subject.

In response to a movement of the camera module ED80 or an electronic apparatus 1101 including the camera module ED80, the image stabilizer 1140 may move one or more lenses included in the lens assembly 1110 or the image sensor 1000 in a specific direction, or perform control on the operation characteristics of the image sensor 1000 (such as adjustment of the read-out timing), such that a negative effect of the movement is compensated. The image stabilizer 1140 may detect a movement of the camera module ED80 or the electronic apparatus ED01, using a gyro sensor or an acceleration sensor disposed inside or outside the camera module ED80. The image stabilizer 1140 may be optically implemented.

The memory 1150 may store some or all data of an image, obtained through the image sensor 1000, for a subsequent image processing task. For example, when a plurality of images is obtained at high speed, the obtained raw image data (such as Bayer-patterned data, high-resolution data, etc.) may be stored in the memory 1150 such that after only low-resolution images are displayed, the raw data of a selected image (such as a user's choice) may be transmitted to the image signal processor 1160. The memory 1150 may be integrated into the memory ED30 of the electronic apparatus ED01, or may be configured as a separate memory which is independently operated.

The image signal processor 1160 may perform image processing on an image obtained through the image sensor 1000 or image data stored in the memory 1150. The image processing may include depth map generation, three-dimensional modeling, panorama generation, feature point extraction, image synthesizing, and/or image compensation (such as noise reduction, resolution adjustment, brightness adjustment, blurring, sharpening, softening, etc.). The image signal processor 1160 may perform control (such as exposure time control, read-out timing control, etc.) on the constituent elements (such as the image sensor 1000) included in the camera module ED80. An image processed by the image signal processor 1160 may be stored back in the memory 1150 for additional processing, or may be provided to a constituent element outside the camera module ED80 (such as the memory ED30, the display device ED60, the electronic apparatus ED02, the electronic apparatus ED04, the server ED08, etc.). The image signal processor 1160 may be integrated into the processor ED20, or may be configured as a separate processor which is operated independently from the processor ED20. When the image signal processor 1160 is configured as a processor separate from the processor ED20, an image processed by the image signal processor 1160 may be subjected to additional image processing by the processor ED20, and then displayed through the display device ED60.

Further, the image signal processor 1160 may independently receive two output signals from or adjacent photosensitive cells inside each pixel or sub pixel of the image sensor 1000, and generate an auto-focus signal from the difference between the two output signals. Based on the auto-focus signal, the image signal processor 1160 may control the lens assembly 1110 to accurately focus the lens assembly 1110 on the surface of the image sensor 1000.

The electronic apparatus ED01 may further include one or more additional camera modules having different attributes or functions, respectively. Such a camera module also may include a component similar to that of the camera module ED80 of FIG. 20, and an image sensor which is provided therein may be implemented as a charged coupled device (CCD) sensor and/or a complementary metal oxide semiconductor (CMOS) sensor, and may include one or more sensors selected from image sensors having different attributes, such as RGB sensors, black and white (BW) sensors, IR sensors, or UV sensors. In this case, of the plurality of camera modules ED80, one may be a wide-angle camera, and another one may be a telephoto camera. Similarly, of the plurality of camera modules ED80, one may be a front camera, and another one may be a rear camera.

According to one or more embodiments, it is possible to provide an image sensor which has a fast operation characteristic while preventing parasitic capacitance and shorts in the image sensor, and an electronic apparatus comprising the image sensor.

Each of the embodiments provided in the above description is not excluded from being associated with one or more features of another example or one or more embodiments also provided herein or not provided herein but consistent with the disclosure.

While the disclosure has been particularly shown and described with reference to embodiments thereof, it will be understood that various changes in form and details may be made therein without departing from the spirit and scope of the following claims.

What is claimed is:

1. An image sensor comprising:
a substrate comprising a first surface and a second surface facing the first surface in a first direction;
a first pixel region and a second pixel region that are isolated by a photodiode isolation pattern in the substrate;
a plurality of active regions adjacent to the first surface of the substrate;
a plurality of gate electrodes on the first surface of the substrate and respectively on the plurality of active regions;
a plurality of gate insulating layers respectively between the plurality of active regions and the plurality of gate electrodes;
a first floating diffusion region in the first pixel region;
a second floating diffusion region in the second pixel region;
a connection portion on the first surface of the substrate; and
an insulating pattern between the substrate and the connection portion,
wherein the first floating diffusion region is connected to the second floating diffusion region by the connection portion, and
wherein, in the first direction, a thickness of the insulating pattern is larger than a thickness of the plurality of gate insulating layers.

2. The image sensor of claim 1, wherein a first portion of the connection portion overlaps the photodiode isolation pattern.

3. The image sensor of claim 2, wherein the insulating pattern is between the connection portion and the photodiode isolation pattern.

4. The image sensor of claim 3, wherein a second portion of the connection portion abuts the first floating diffusion region and the second floating diffusion region.

5. The image sensor of claim 4, wherein the connection portion comprises a first extension portion in a groove in the first floating diffusion region and a second extension portion in a groove in the second floating diffusion region.

6. The image sensor of claim 1, wherein the plurality of gate electrodes comprise a source follower gate electrode,
wherein the plurality of gate insulating layers comprise a first gate insulating layer below the source follower gate electrode, and
wherein remaining gate insulating layers of the plurality of gate insulating layers have a thickness in the first direction that is larger than a thickness of the first gate insulating layer in the first direction.

7. The image sensor of claim 6, wherein a first pixel corresponds to the first pixel region and a second pixel corresponds to the second pixel region,
wherein the image sensor further comprises a third pixel adjacent to the first pixel, and
wherein the source follower gate electrode is positioned in the first pixel and in the third pixel.

8. The image sensor of claim 7, wherein a first portion of the connection portion overlaps the photodiode isolation pattern.

9. The image sensor of claim 8, wherein the insulating pattern is between the connection portion and the photodiode isolation pattern.

10. The image sensor of claim 9, wherein a second portion of the connection portion abuts the first floating diffusion region and the second floating diffusion region.

11. The image sensor of claim 1, wherein the plurality of gate electrodes comprise a source follower gate electrode, and
wherein the connection portion comprises an extension connection portion that extends to the source follower gate electrode.

12. The image sensor of claim 11, wherein the insulating pattern extends below the extension connection portion.

13. The image sensor of claim 12, wherein the source follower gate electrode, the connection portion, and the extension connection portion comprise the same material.

14. The image sensor of claim 12, wherein the extension connection portion overlaps a portion of at least one active region of the plurality of active regions, and
wherein the insulating pattern is between the extension connection portion and the portion of the at least one active region.

15. The image sensor of claim 14, wherein a first portion of the connection portion overlaps the photodiode isolation pattern.

16. The image sensor of claim 15, wherein the insulating pattern is between the connection portion and the photodiode isolation pattern.

17. The image sensor of claim 16, wherein a second portion of the connection portion abuts the first floating diffusion region and the second floating diffusion region.

18. The image sensor of claim 1, wherein the plurality of gate electrodes and the connection portion comprise the same material.

19. The image sensor of claim 18, wherein a first portion of the connection portion overlaps the photodiode isolation pattern, and
wherein the insulating pattern is between the connection portion and the photodiode isolation pattern.

20. An electronic apparatus comprising:
a lens assembly configured to form an optical image of a subject;
an image sensor configured to convert the optical image formed by the lens assembly into an electrical signal; and
a processor configured to process the electrical signal generated by the image sensor,
wherein the image sensor comprises:
a substrate comprising a first surface and a second surface facing the first surface in a first direction;
a first pixel region and a second pixel region that are isolated by a photodiode isolation pattern in the substrate;
a plurality of active regions adjacent to the first surface of the substrate;
a plurality of gate electrodes on the first surface of the substrate and respectively on the plurality of active regions;
a plurality of gate insulating layers respectively between the plurality of active regions and the plurality of gate electrodes;
a first floating diffusion region in the first pixel region;
a second floating diffusion region in the second pixel region;
a connection portion on the first surface of the substrate; and
an insulating pattern between the substrate and the connection portion,
wherein the first floating diffusion region is connected to the second floating diffusion region by the connection portion, and
wherein, in the first direction, a thickness of the insulating pattern is larger than a thickness of the plurality of gate insulating layers.
